(19) United States
(12) Patent Application Publication
(10) Pub. No.: US 2014/0322834 A1
(43) Pub. Date: Oct. 30, 2014

(54) APPARATUS AND METHOD FOR BONDING SUBSTRATES

(71) Applicant: LTrin Co., Ltd, Seoul (KR)

(72) Inventors: Yong Won CHA, Seoul (KR); Chang Woo RYOO, Gyeonggi-do (KR); Sang Jun OH, Gyeonggi-do (KR); Gun Woo PARK, Gyeonggi-do (KR); Jae In PARK, Gyeonggi-do (KR)

(73) Assignee: LTrin Co., Ltd, Seoul (KR)

(21) Appl. No.: 14/263,342

(22) Filed: Apr. 28, 2014

Related U.S. Application Data
(60) Provisional application No. 61/817,624, filed on Apr. 30, 2013.

(51) Int. Cl. H01L 21/66; H01L 21/68

(52) U.S. Cl. CPC H01L 22/12; H01L 21/68
USPC 438/15; 156/363

(57) ABSTRACT

An apparatus for bonding substrates and a method of bonding substrates are provided. In accordance with one exemplary embodiment of the present invention, a first plate to mount a first substrate is provided. A chamber body movably connected to the first plate is provided. A second plate that is placed opposite to the first plate and a second substrate is mounted on the second plate is provided. A chamber lead having the second plate mounted inside is provided which is movably connected to the chamber body to move rotationally or linearly to open or close the chamber space with the chamber body. A pair of first alignment cameras is placed outside of the chamber space to scan the first substrate or the second substrate. A stage control unit is provided to move the first plate or the second plate to align the first substrate and the second substrate.

### CROSS REFERENCE TO RELATED APPLICATIONS

This application is a non-provisional of and claims the benefit of U.S. provisional patent application No. 61/817,624 filed on Apr. 30, 2013, the disclosure of which is incorporated herein by reference in its entirety.

### BACKGROUND

1. Field

The exemplary embodiments disclosed herein relate to a substrate processing apparatus, especially an apparatus for bonding substrates and a method of boding substrates with the apparatus.

2. Brief Description of Related Developments

Substrates bonding techniques have been used in MEMS technology or multi-chip lamination technology. Previously, substrates were bonded with adhesive and wiring was done later, therefore precise alignment of the substrates was not required. However, since techniques to connect wirings formed on the substrates directly through bonding and to create electric couplings are now used, it is necessary to align the substrates precisely before bonding procedure. For example, there are current systems and methods where the substrates are precisely aligned at the outside of bonding chamber and moved together as aligned to the bonding chamber, and then bonding procedure is performed.

However, using the current systems and methods has shown that it is difficult to keep the substrates precisely aligned during movement. Also, since alignment and bonding are done in separate locations, the structure of apparatus also becomes much more complex.

The present invention overcomes the problems described above and other issues. Its purpose is providing a substrate bonding apparatus that performs alignment and bonding in the same chamber and a method of bonding substrates utilizing the apparatus. It should be understood that the following description is only illustrative of the exemplary embodiment. Various alternatives and modifications can be devised by those skilled in the art without departing from the exemplary embodiment.

### SUMMARY OF THE EXEMPLARY EMBODIMENTS

In accordance with one aspect of the exemplary embodiment a substrate bonding apparatus is provided. A first plate to mount a first substrate is provided. A chamber body movably connected to the first plate is provided. A second plate positioned opposite to the first plate and a second substrate mounted on the second plate is provided. A chamber lead having the second plate mounted inside and which is movably connected to the chamber body to move rotationally or linearly to open or close the chamber space with the chamber body. A pair of first alignment cameras is placed outside of the chamber space to scan the first substrate or the second substrate. A stage control unit is provided to move the first plate or the second plate to align the first substrate and the second substrate.

In one aspect of the exemplary embodiment, the apparatus further comprises a Z-axis control unit to move the first plate or the second plate vertically to the first substrate and the second substrate to bond the first substrate and the second substrate.

In one aspect of the exemplary embodiment, for the bonding substrate apparatus, the chamber lead has at least one pair of holes that pierce through the chamber lead and the second plate to expose the rear side of the second substrate.

In one aspect of the exemplary embodiment, for the bonding substrate apparatus, the pair of first alignment cameras is mounted on the first plate to scan a front side of the first substrate when the chamber body rotates relative to the chamber lead or moves pivotally relative to the chamber lead.

In one aspect of the exemplary embodiment, the apparatus further comprises at least a second alignment camera(s) placed outside of the chamber and under the second plate to scan a front side of the second substrate when the chamber lead moves pivotally relative to the chamber body.

In one aspect of the exemplary embodiment, for the bonding substrate apparatus, the pair of first alignment cameras is mounted on the chamber lead and the at least one second alignment cameras is mounted opposite to the pair of the first alignment camera(s) outside of the chamber space and under the chamber body.

In one aspect of the exemplary embodiment, for the bonding substrate apparatus, the chamber body has a floating part where the chamber lead is connected to the chamber body.

In one aspect of the exemplary embodiment, the bonding substrate apparatus further comprises at least one laser sensor to confirm the position and horizontality of the chamber lead.

In accordance with another aspect of the exemplary embodiment a method of bonding substrates is provided. The method comprises placing a first substrate on a first plate mounted inside of a chamber body and placing the second substrate on the second plate mounted opposite to the first plate inside of the chamber lead which is movably fixed to the chamber body, exposing a front side of the first substrate to an outside of a chamber space after rotating the chamber body pivotally to the chamber lead or moving the chamber body horizontally, scanning the first substrate using first alignment cameras mounted on the chamber lead, scanning the second substrate after rotating the chamber lead or moving the chamber lead horizontally, and aligning the first substrate and the second substrate to each other by moving the first plate or the second plate.

In one aspect of the exemplary embodiment, the method of bonding substrate further comprises bonding the first substrate and the second substrate by moving the first plate or the second plate vertically to the first substrate and the second substrate.

In one aspect of the exemplary embodiment, for the method of bonding substrate, scanning the second substrate is done by at least one pair of the first alignment cameras scanning the bottom side of the second substrate through the at least a pair of holes piercing through the chamber lead and the second plate.

In one aspect of the exemplary embodiment, for the method of bonding substrate, scanning the second substrate further comprises moving the chamber lead pivotally relative to the chamber body or horizontally to expose the front side of the second substrate to the outside of the chamber space; and having the at least one pair of the second alignment cameras mounted under the chamber body scan the front side of the second substrate.

As described above, in accordance with one aspect of the exemplary embodiment of the of the substrate bonding apparatus and the method of bonding substrate, aligning of the substrates and bonding the substrates are done inside of the same chamber without transferring the substrates, which results in simpler process. Furthermore, since the substrates are fixed to the plates, the reliability of the process is improved by preventing the misalignment of the substrates. It should be understood that the foregoing effects are only exemplary. Various alternatives and modifications can be devised by those skilled in the art without departing from the exemplary embodiment.

### BRIEF DESCRIPTION OF THE DRAWINGS

FIG. 1 is a schematic view of a substrate bonding apparatus in accordance with an exemplary embodiment;

FIGS. 2 and 3 are schematic views of a method of bonding substrates in accordance with another exemplary embodiment;

FIGS. 4 and 5 are schematic views of a method of bonding substrates in accordance with another exemplary embodiment;

### DETAILED DESCRIPTION OF THE EXEMPLARY EMBODIMENTS

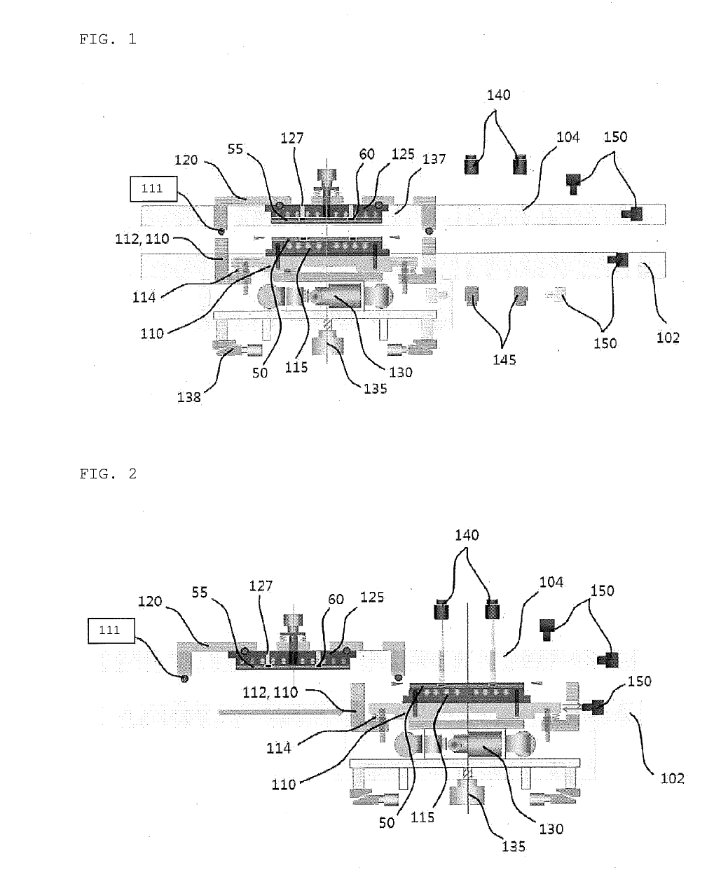

FIG. 1 illustrates a schematic view of a substrate bonding apparatus in accordance with an aspect of the disclosed embodiment. Although the aspects of the disclosed embodiment will be described with reference to the drawings, it should be understood that the aspects of the disclosed embodiment can be embodied in many forms. In addition, any suitable size, shape or type of elements or materials could be used.

FIG. 1 is a schematic view of a substrate bonding apparatus in accordance with an exemplary embodiment.

Referring to FIG. 1, a chamber body 110 that is movably connected to a chamber lead 120 is provided. The chamber body 110 and the chamber lead 120 may rotate or move horizontally or vertically relative to each other and are combined together to close a chamber space 137 or pivotally positioned to open the chamber space 137. In one exemplary embodiment, the chamber body 110 is concave in a downward direction and the chamber lead 120 is convex in an upward direction. Thereinafter, if the chamber lead 120 and the chamber body 110 are combined as aligned to each other, the closed chamber space 137 is shut tight.

Additionally, the chamber body 110 and the chamber lead 120 are mounted opposite to each other; and closed using an airtight unit 111. The space may be kept vacuous using a vacuum pump (not shown). For example, the airtight unit 111 may include rubber material such as O-ring, or any other suitable materials. The airtight unit 115 may have various shapes and in one aspect of the exemplary embodiment may have the same shape with the cross section of the chamber body 110 and the chamber lead 120. For example, if the chamber body 110 and the chamber lead 120 are circular-shaped; the airtight unit 111 can have a circular-shape. For another exemplary embodiment, if the chamber body 110 and the chamber lead 120 are polygonal-shaped; the airtight unit 111 may have a polygonal shape.

In one aspect of the embodiment, the chamber body 110 has a floating unit 112 where the chamber body 110 is connected to the chamber lead 120. The floating unit 112 uses elastic material 114 such as a spring to elastically connect itself to the chamber body 110 and to be able to float separately from the chamber body 110 even though the main part of chamber body 110 is fixed. Thereinafter, the floating unit 112 of the chamber body 110 can move or float relative to the fixed portion of the chamber body 110.

The floating unit 112 absorbs impact to the chamber body 110 and the chamber lead 120 and prevents vacancy of the chamber space 137 from movement of the airtight unit 115.

The chamber body 110 may rotate or move horizontally along a bottom axis 102. The chamber lead 120 may rotate or move generally horizontally along a top axis 104. The horizontal direction may be generally parallel to the surface of the chamber body 110 and the chamber lead 120. In one aspect of the exemplary embodiment, the chamber body 110 and the chamber lead 120 moves along the top axis 104 or the bottom axis 102 using a linear motor or any other suitable movement mechanism. Additionally, the chamber body 110 may move to Z-axis direction, generally vertically or upwards or away from the parallel direction described above to close or open the chamber space 137.

The first plate 115 is provided inside the chamber body 110 so that the first substrate 50 may be mounted on the plate 115. In one aspect of the embodiment, the first plate 115 is mounted inside the chamber body 110 so that the front part of the first substrate 50 faces the inside of chamber space 137 (upward direction). In one aspect of the embodiment, the first substrate 50 may be mounted on the first plate 115 using vacuum pressure. In another aspect of the embodiment, the first substrate 50 may be mounted on the first plate 115 using static electricity, physical clamping or any other suitable holding means.

The second plate 125 is provided inside the chamber lead 120 opposite to the first plate 115. In one aspect of the embodiment, the second plate 125 is mounted inside the chamber lead 120 so that the front part of the second substrate faces the inside of chamber space 137 (downward direction). In one aspect of the embodiment, the second substrate 55 may be mounted on the second plate 125 using vacuum pressure. In another aspect of the embodiment, the second substrate 55 may be mounted on the second plate 125 using static electricity, physical clamping or any other suitable holding means.

The chamber lead 120 may have at least one pair of holes 127 piercing continuously through the second plate 125 and the chamber lead 120. The holes 127 may be called as view port since they are used as a port to monitor or take images of the rear side of the second substrate 55. There may be any number of holes 127 and the size and shape may be adjusted as necessary.

A first alignment camera(s) 140 (e.g. a pair is shown for example) is provided to determine the position of the first substrate 50 and/or the second substrate 55 by scanning the substrates 50, 55 (more or fewer cameras may be provided). In one aspect of the embodiment, the first and second substrate 50, 55 have alignment keys 60 at the front or rear side of the substrates and the first alignment cameras 140 may scan the alignment keys 60. In one aspect of the exemplary embodiment, the first alignment camera(s) 140 is placed outside of the chamber space 137 and on the chamber lead 120 and/or the top axis 104 not to interrupt the movement of the chamber body 110 and the chamber lead 120.

In one aspect of the embodiment, the first alignment cameras 140 are placed to scan the front side of the first substrate 50 when the chamber body 110 moves pivotally relative to the chamber lead 120. For this purpose, the first alignment cameras 140 are mounted at least on the first plate 115. In another aspect of the embodiment, the first alignment cameras 140 scan the rear side of the second substrate 55 through the holes 127 when the chamber body 110 aligns or is placed pivotally relative to the chamber lead 120. In this case, the alignment keys 60 of the second substrate 55 may be at the rear side of the second substrate 55. For this purpose, the first alignment cameras 140 are mounted at least on the chamber lead 120.

Additionally, one or more (e.g. a pair) of the second alignment camera(s) 145 may be provided to scan the front side of the second substrate 55. In one aspect of the exemplary embodiment, the second alignment cameras 145 are placed under the second plate 125 to scan the front side of the second substrate 55 when the chamber lead 120 moves pivotally relative to the chamber body 110. In one aspect of the exemplary embodiment, the second alignment cameras 145 is placed outside of the chamber space 137 and under the chamber body 110 and/or the bottom axis 102 not to interrupt the movement of the chamber body 110 and the chamber lead 120. Optionally, the second alignment cameras 145 are placed opposite or symmetrically to the first alignment cameras 140.

The first alignment cameras 140 and the second alignment cameras 145 may be CCD (charge coupled device) or CMOS (complementary metal-oxide-semiconductor) or other various types. Additionally, at least 2 of the first alignment cameras 140 and the second alignment cameras 145 are placed to determine position from the alignment keys 60, but the number of cameras are not restricted to the exemplary embodiments. In another aspect of the exemplary embodiment, if the first alignment cameras 140 scan both of the first substrate 50 and the second substrate 55, the second alignment cameras 145 may be omitted.

Additionally, a laser sensor 150 may be provided to confirm the position and horizontality of the chamber body 110 or the chamber lead 120. In one aspect of the exemplary embodiment, at least one laser sensor 150 is provided near the bottom axis 102 to check the position and horizontality of the chamber body 110 and at least one laser sensor 150 is provided near the top axis 104 to check the position and horizontality of the chamber lead 120.

A stage control unit 130 is provided to move the first plate 115 and/or the second plate 125 to align the first substrate 50 and the second substrate 55. In one aspect of the exemplary embodiment, the stage control unit 130 moves the first plate 115 to align the alignment keys 60 of the first and second substrates 50, 55 using position information from the first alignment cameras 140 and/or the second alignment cameras 145. The stage control unit 130 controls the first plate 115 on x-y-θ axis to move it horizontally to both linear directions.

Tilt control unit 138 is provided optionally to control horizontal tilt of the first plate 115 and/or the second plate 125.

Z-axis control unit 135 moves the first plate 115 and/or the second plate 125 vertically relative to the first substrate 50 and the second substrate 55 to bond the first substrate 50 and the second substrate 55. In one aspect of the exemplary embodiment, Z-axis control unit 135 moves the first plate 115 vertically to upper direction to bond the first substrate 50 and the second substrate 55. In another aspect of the exemplary embodiment, Z-axis control unit 135 controls the second plate 125 or both of the first plate 115 and the second plate 125. In this aspect of the exemplary embodiment, the first plate 115 is fixed to the chamber body 110 and the Z-axis control unit 135 moves the first plate 115 vertically by moving the chamber body 110 vertically.

With the substrates bonding apparatus in this aspect of the exemplary embodiment, the chamber space 137 is closed or open by moving the chamber body 110 and the chamber lead 120 relatively to each other. Substrate alignment and substrate bonding are done in the same chamber without moving the substrates 50, 55 and therefore the procedure is simplified. Also, the substrates 50, 55 are mounted on the plates 115, 125 so that mis-alignment of the substrates from their movement is prevented.

The substrates bonding apparatus in this aspect of the exemplary embodiment can be applied to MEMS technology, imaging sensor technology, and lamination packaging technology. For example, the first substrate 50 and the second substrate 55 may be semiconductor wafer.

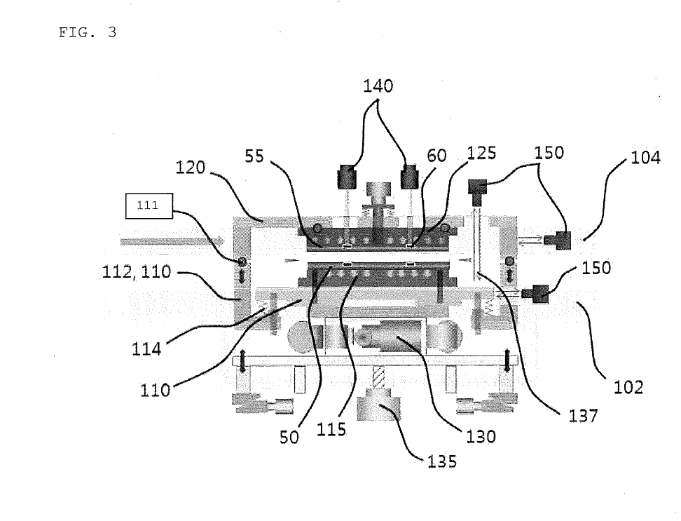

FIGS. 2 and 3 are schematic views of a method of bonding substrates in accordance with an aspect of the exemplary embodiment.

First, as described in FIG. 1, the first substrate 50 is mounted on the first plate 115 that is fixed to the inside of the chamber body 110. The second substrate 55 is mounted on the second plate 125 that is fixed to the inside of the chamber lead 120. The order of mounting the first substrate 50 and the second substrate 55 is established as desired and the order does not limit the exemplary embodiment. In one aspect of the exemplary embodiment, the first substrate 50 and the second substrate 55 are mounted on the first plate 115 and the second plate 125 using vacuum pressure. As noted, the order of mounting the first substrate 50 and the second substrate 55 may be as desired and does not limit the one or more aspects of the exemplary embodiment.

Referring to FIG. 2, the front side of the first substrate 50 is exposed to the outside of the chamber space 137 by moving the chamber body 110 and the chamber lead 120 (e.g. pivotally) relative each other. In one aspect of the exemplary embodiment, the laser sensor 150 checks the position and horizontality of the chamber body 110 and the chamber body 110 moves so that the first alignment cameras 140 are disposed on the first plate 115. Therefore, the front side of the first substrate 50 is exposed to the outside of the chamber space 137 so that the first alignment cameras face the front side of the first substrate 50. In another aspect of the exemplary embodiment, the first body 110 may translate to expose the front side of the first substrate 50 to the outside of the chamber body 110.

Subsequently, the first alignment cameras 140 on the chamber lead 120 scans the first substrate 50. Therefore, the position information, such as the position of the alignment keys 60 of the first substrate 50 is collected.

Referring to FIG. 3, the chamber lead 120 moves horizontally to the chamber body 110 and the alignment cameras 140 scan the rear side of the second substrate 55 through the holes 127 piercing through the chamber lead 120 and the second plate 125. Subsequently, the position information, such as the position of the alignment keys 60 of the second substrate 55 is collected. In this aspect of the exemplary embodiment, the first substrate 50 and the second substrate 55 are scanned using a front-back scanning method. In another aspect of the exemplary embodiment, the rear side of the second substrate 55 is exposed to the outside of the chamber space 137 by rotating or otherwise moving the chamber lead 120.

Subsequently, the stage control unit 130 moves the first plate 115 and/or the second plate 125 to align the first substrate 50 and the second substrate 55. In one aspect of the exemplary embodiment, the stage control unit 130 aligns the alignment keys 60 of the substrates 50, 55 using the position information of the substrates 50, 55.

Subsequently, the Z-axis control unit 135 moves the first plate 115 and the second plate 125 vertically to align the first substrate 50 and the second substrate 55 and bond them together. In one aspect of the exemplary embodiment, during the bonding process, diffusion bonding can be induced by aligning the first substrate 50 and the second substrate 55 in vacuum and providing proper heating.

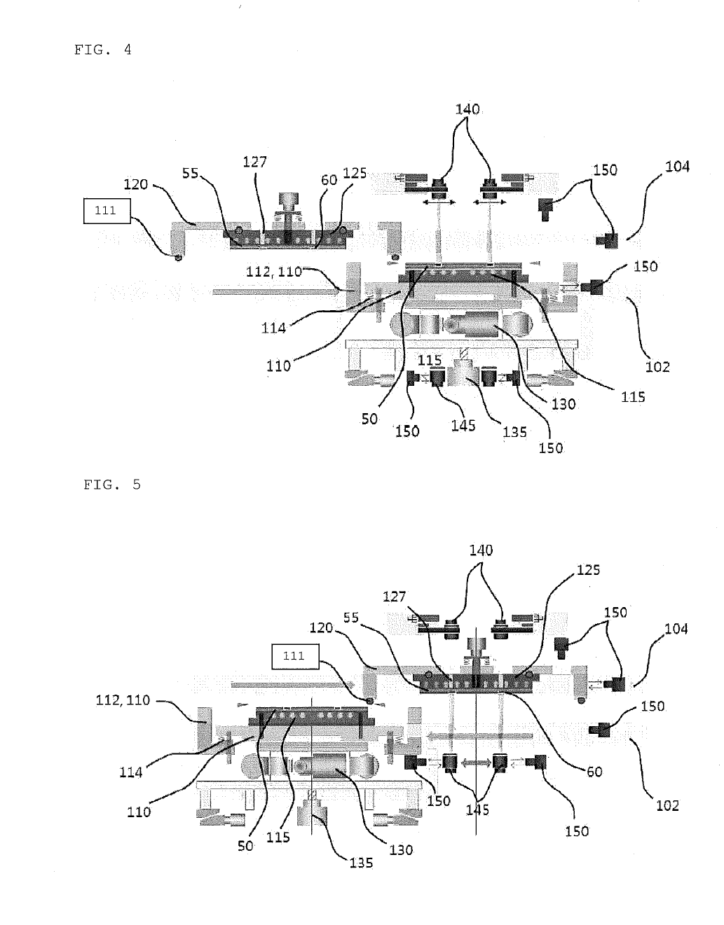

FIGS. 4 and 5 are schematic views of a method of bonding substrates in accordance with another aspect of the exemplary embodiment.

Referring to FIG. 4, moving the chamber body 110 pivotally relative to the chamber lead 120 exposes the front side of the first substrate 50 to the outside of the chamber space 137. Subsequently, the front side of the first substrate 50 is exposed to the outside of the chamber space 137 so that it faces the first alignment cameras 140. Then, the first alignment cameras 140 that are mounted on the chamber lead 120 scans the first substrate 50. Subsequently, the position information, for example the position information of the alignment keys 60, is collected.

Referring FIG. 5, moving the chamber lead 120 horizontally relative to the chamber body 110 exposes the front side of the second substrate 55 to the outside of the chamber space 137. Subsequently, the second alignment cameras 145 mounted under the chamber body 110 scans the front side of the second substrate 55. Subsequently, the position information of the second substrate 55, for example the position information of the alignment keys 60, is collected. Normally, the alignment keys 60 are formed in the front side of the substrates 50, 55. Therefore, in one aspect of the exemplary embodiment, the front-front scanning method having the front side of the first substrate 50 opposite the front side of the second substrate 55, is used primarily.

Subsequently, as stated in one or more aspects of the exemplary embodiments, the stage control unit 130 moves the first plate 115 and/or the second plate 125 to align the first substrate 50 and the second substrate 55 to each other. And, Z-axis control unit 135 moves the first plate 115 or the second plate 125 vertically to place the first substrate 50 and the second substrate 55 close to each other. And then, bonding process is done after shutting tight the chamber space 137.

Following the bonding procedure described in the prior aspect of the exemplary embodiments, the position information of the second substrate 55 is collected when the alignment keys 60 is on the rear side of the substrate as when the alignment keys 60 is on the front side of the substrate. Also, the alignment and bonding procedure are done when the substrates 50, 55 are mounted on the plates 115, 125. Therefore, the process is simplified and the reliability of the process is increased.

It should be understood that the foregoing description is only illustrative of the aspects of the disclosed embodiment. Various alternatives and modifications can be devised by those skilled in the art without departing from the aspects of the disclosed embodiment. Accordingly, the aspects of the disclosed embodiment are intended to embrace all such alternatives, modifications and variances that fall within the scope of the appended claims. Further, the mere fact that different features are recited in mutually different dependent or independent claims does not indicate that a combination of these features cannot be advantageously used, such a combination remaining within the scope of the aspects of the invention.

What is claimed is:

1. A substrate bonding apparatus comprises a first plate configured to mount a first substrate; a chamber body movably connected to the first plate; a second plate positioned opposite to the first plate and configured to mount a second substrate; a chamber lead having the second plate mounted inside and movably connected to the chamber body, wherein the chamber body is configured to move rotationally or linearly relative to the chamber lead to open or close the chamber space; a pair of first alignment cameras positioned outside of the chamber space configured to scan the first substrate or the second substrate; and a stage control unit configured to move the first plate or the second plate to align the first substrate and the second substrate.

2. The bonding apparatus according to claim 1, further comprising Z-axis control unit configured to move the first plate or the second plate vertically to the first substrate and the second substrate to bond the first substrate and the second substrate.

3. The bonding apparatus according to claim 1, wherein the chamber lead has at least one pair of holes piercing through the chamber lead and the second plate to expose the rear side of the second substrate.

4. The bonding apparatus according to claim 1, wherein the pair of first alignment cameras is mounted on the first plate to scan a front side of the first substrate when the chamber body rotates relative to the chamber lead or moves pivotally relative to the chamber lead.

5. The bonding apparatus according to claim 1, further comprising second alignment cameras outside of the chamber and under the second plate configured to scan a front side of the second substrate when the chamber lead moves pivotally relative to the chamber body.

6. The bonding apparatus according to claim 1, wherein the pair of first alignment cameras is mounted on the chamber lead and the pair of second alignment cameras is mounted opposite to the pair of the first alignment cameras at outside of the chamber space and under the chamber body.

7. The bonding apparatus according to claim 1, wherein the chamber body has a floating part where the chamber lead is connected to the chamber body.

8. The bonding apparatus according to claim 1, further comprising at least one laser sensor to confirm the position and horizontality of the chamber lead.

9. A method of bonding substrates comprises mounting a first substrate on a first plate that is fixed to inside of a chamber body and mounting a second substrate on a second plate that is fixed opposite to the first plate inside of a chamber lead which is movably connected to the chamber body; exposing a front side of the first substrate to outside of a chamber space by rotating the chamber body pivotally to the chamber lead or moving the chamber body horizontally; scanning the first substrate using the first alignment cameras mounted on the chamber lead; scanning the second substrate after rotating the chamber lead or moving the chamber lead horizontally; and aligning the first substrate and the second substrate to each other by moving the first plate or the second plate.

10. The bonding apparatus according to claim 9, further comprising bonding the first substrate and the second substrate by moving the first plate or the second plate vertically to the first substrate and the second substrate.

11. The bonding apparatus according to claim 9, wherein scanning the second substrate is done by the at least one pair of alignment cameras scanning the bottom side of the second substrate through the at least one pair of holes piercing through the chamber lead and the second plate.

12. The bonding apparatus according to claim 9, wherein scanning the second substrate further comprises moving the chamber lead pivotally relative to the chamber body or horizontally to expose the front side of the second substrate to the outside of the chamber space; and having the at least one pair of the second alignment cameras mounted under the chamber body scan the front side of the second substrate.
